(19) United States
(12) Patent Application Publication
(10) Pub. No.: US 2008/0289957 A1
(43) Pub. Date: Nov. 27, 2008

(54) Vacuum Film Forming Apparatus

(75) Inventors: Shirou Takigawa, Hyogo (JP); Keiji Katou, Hyogo (JP); Nobuo Yoneyama, Hyogo (JP)

Correspondence Address: MARSHALL, GERSTEIN & BORUN LLP, 233 S. WACKER DRIVE, SUITE 6300, SEARS TOWER, CHICAGO, IL, 60606, US

(73) Assignee: Shinmaywa Industries, LTD.

(21) Appl. No.: 11/662,563

(22) PCT Filed: Sep. 5, 2005
(86) PCT No.: PCT/JP05/16218

§ 371 Date: Feb. 27, 2008

(30) Foreign Application Priority Data
Sep. 14, 2004 (JP) 2004-266878

(51) Int. Cl. C23C 14/34; C23C 14/35

(52) U.S. Cl. 204/298.11; 204/298.12; 204/298.16

(57) ABSTRACT

A vacuum film forming apparatus is provided that is intended to use a portion of its cylindrical member as a target and moreover have an additional function of plasma polymerization using the cylindrical member.

A vacuum film forming apparatus (100) is provided with an electrically conductive vacuum chamber (13) having an interior space, a frame member (15) having a plurality of curved members (31, 32) each curved in a sector shape and arranged in the interior space (10) so as to form a substantially cylindrical shape, and a magnetic field forming device (33) disposed in an interior surrounded by the frame member (15) and configured to form a magnetic field along the circumference of the frame member (15). At least one of the curved members (15, 16) is a target used for sputtering, and a region of the frame member (15) other than the target is used for plasma polymerization.

### TECHNICAL FIELD

The present invention relates to a vacuum film forming apparatus, and more particularly to the vacuum film forming apparatus in which a magnetic field forming device is disposed in a substantially cylindrical hollow frame member.

### BACKGROUND ART

A reflector used for vehicle headlights and taillights has a multilayer film formed on a plastic substrate. In the multilayer film, a protective film (SiOx film) of hexamethyl-disilazane (hereinafter referred to as “HMDS”) is stacked over an aluminum reflector film.

In forming such a multilayer film on the plastic substrate, aluminum deposition with a sputtering apparatus and HMDS deposition with a plasma polymerization apparatus have been performed conventionally. It is therefore desirable that both the sputtering process and the plasma polymerization process be performed with a single vacuum chamber so that the aluminum reflector film and the SiOx film can be continuously formed.

However, improvements to a flat plate target sputtering apparatus, which is used commonly and widely, have limitations in terms of increasing the efficiency of the film formation process that has both functions of sputtering and plasma polymerization (for example, in terms of reduction in cycle time or achieving longer lifespan of the target). For this reason, the inventors of the present application consider it essential to make drastic improvement in the configuration of the target in the sputtering apparatus, such as making the target in a cylindrical configuration, from the viewpoint of increasing the efficiency in the film formation process for reflectors.

As one example of the development of the sputtering apparatus using a cylindrical target, an sputtering apparatus is known in which a plurality of cylindrical targets made of different materials from one another are aligned and a magnet is disposed inside each cylindrical target such as to generate a magnetron magnetic field between adjacent cylindrical targets, whereby the cylindrical targets are sputtered (see Patent Reference 1).

Another example is a sputtering apparatus in which a swing-type magnet is disposed in the interior of a rotatable cylindrical target so that various parts of the outer circumferential surface of the cylindrical target can be uniformly sputtered (see Patent Reference 2).

Another example is a sputtering apparatus in which different kinds of gases are introduced into respective separated spaces of a vacuum chamber that are separated by partition plates, and, while a cylindrical target is being rotated, the target surface is exposed to the gases one after another, whereby a sputter product is coated on a substrate in one of the divided spaces while the target surface is cleaned in another one of the divided spaces (see Patent Reference 3).

Another example is a sputtering apparatus in which a cylindrical target is divided into two regions made of different compositions, and these are rotated at an appropriate angle, whereby an alloy film containing respective different compositions at desired proportions can be formed (see Patent Reference 4).

[Patent Reference 1]

Japanese Unexamined Patent Publication No. 3-104864

[Patent Reference 2]

Japanese Unexamined Patent Publication No. 11-29866

[Patent Reference 3]

Japanese Unexamined Patent Publication No. 5-263225

[Patent Reference 4]

Japanese Unexamined Patent Publication No. 2003-183823

### DISCLOSURE OF THE INVENTION

### Problems the Invention is to Solve

Nevertheless, none of Patent References 1 to 4 shows the technical idea that while using a portion of the cylindrical member as a target, the cylindrical member is also used to serve the function of plasma polymerization.

Moreover, none of Patent References 1 to 4 appropriately copes with the non-uniformity in the target erosion originating from the magnetic field conditions at the axial end of a target when forming the magnetic field along the width of a curved surface of the target that curves widthwise and extends axially. Furthermore, none of Patent References 1 to 4 even notices the problem of non-uniformity in erosion.

What is more, none of Patent References 1 to 4 discloses a technique to adjust deposition distribution of particles deposited on a substrate by an interaction of magnetic fields generated by magnetic field forming devices that are provided in a pair of cylindrical members disposed adjacent to each other.

The present invention has been accomplished in view of the foregoing circumstances, and it is an object of the present invention to provide a vacuum film forming apparatus that uses a portion of a cylindrical member (more precisely, a substantially cylindrical member comprising a plurality of curved members each curved in a sector shape) as a sputtering target and that has an additional function of plasma polymerization using the cylindrical member.

It is another object of the present invention to provide a vacuum film forming apparatus that can appropriately cope with the non-uniformity in the target erosion originating from the magnetic field conditions at the axial end of the target curving widthwise and extending axially, when forming the magnetic field along the width of the curved surface of the target.

It is yet another object of the present invention to provide a vacuum film forming apparatus that adjusts deposition distribution of particles deposited on a substrate by an interaction of magnetic fields generated by magnetic field forming devices that are provided in a pair of hollow frame members disposed adjacent to each other.

### Means to Solve the Problems

In order to accomplish the foregoing objects, the present invention provides a vacuum film forming apparatus comprising: an electrically conductive vacuum chamber having an interior space; a target disposed in the interior space, having a curved surface curved widthwise and extending axially; a magnetic field forming device configured to form a magnetic field along a width of the curved surface of the target; and an electrically conductive shield plate having an opening facing an axially central portion of the curved surface and being disposed such that the curved surface is opposed to an end surface of the opening, wherein the curved surface that is positioned at an axial end portion of the target is covered by the shield plate. It is desirable that the shield plate covers the curved surface positioned at both axial end portions of the target.

More specifically, the shield plate is bent so as to conform to a curve shape of the curved surface, whereby the curved surface that is positioned at an axial end portion of the target is covered by the shield plate.

With this configuration, the curved surface of the target that corresponds to an axial end portion of the target is covered with the shield plate. Thus, it becomes possible to appropriately cope with the non-uniformity in the target erosion originating from the magnetic field conditions at the axial ends of the target.

The shape of the target may be in a substantially cylindrical shape comprising a plurality of curved members each curved in a sector shape.

This makes it possible to prolong the life span of the target to the maximum.

The shield plate may be an earth shield plate connected to the vacuum chamber that is in a grounded state.

Such a configuration allows the plasma formed by gas ionization due to electric discharge to disappear at the end surface of the opening of the earth shield plate, whereby abnormal electric discharge in the vicinity of the earth shield plate is prevented appropriately.

Here, the vacuum film forming apparatus further comprises a plate disposed between the target and the magnetic field forming device, and wherein a predetermined electric power is applied to the plate, to form plasma in the vicinity of the curved surface of the target that protrudes from the opening.

In addition, for the purpose of maximizing the life span of the target by controlling the sputtering so as to scrape away the curved surface of the target uniformly, the target may be configured to be rotatable around its axis. Likewise, the magnetic field forming device may be configured to be rotatable along the width of the curved surface of the target, independently from the rotation of the target.

The present invention also provides a vacuum film forming apparatus comprising: an electrically conductive vacuum chamber having an interior space; a frame member in which a plurality of curved members each curved in a sector shape are arranged in the interior space to form a substantially cylindrical shape; and a magnetic field forming device that is disposed in an interior surrounded by the frame member and is configured to form a magnetic field along a circumference of the frame member, wherein at least one of the curved members is a target used for sputtering, and a region of the frame member other than the curved member that corresponds to the target is used for plasma polymerization.

The vacuum film forming apparatus as described above can perform sputter deposition that uses, as a sputtering target, one curved member among the members of the substantially cylindrical member made up of a plurality of curved members each curved in a sector shape, and can perform plasma polymerization deposition using the region other than the curved member.

In addition, for the purpose of maximizing the life span of the target by controlling the sputtering so as to scrape away the curved surface of the target uniformly, the frame member may be configured to be rotatable around its axis. Likewise, the magnetic field forming device may be configured to be rotatable along the circumference of the curved surface of the target, independently from the rotation of the frame member.

In order that a magnetic field can be reliably formed on the outer circumferential surface of the frame member, the vacuum film forming apparatus may be configured such that the magnetic field forming device comprises a plurality of magnets, and a sector-shaped yoke portion being configured to hold the magnets and being substantially parallel to an inner circumferential surface of the frame member.

Here, the vacuum film forming apparatus may comprise a cylindrical plate disposed between the frame member and the magnetic field forming device, and a predetermined electric power is applied to the plate to form plasma in the vicinity of an outer circumferential surface of the frame member.

The present invention also provides a vacuum film forming apparatus comprising: an electrically conductive vacuum chamber having an interior space; first and second hollow cylindrical frame members arranged in the interior space so as to be lined up and spaced apart from each other; first and second magnetic field forming devices disposed inside the first hollow frame member and the second hollow frame member, respectively, the first magnetic field forming device being configured to form a first magnetic field along the circumference of the first hollow frame member and the second magnetic field forming device being configured to form a second magnetic field along the circumference of the second hollow frame member; and a substrate having a deposition surface on which particles ejected from the first and second hollow frame members due to the first and second magnetic fields are to be deposited, the substrate being disposed such that the deposition surface is exposed to the interior space, wherein the first and the second magnetic field forming devices are brought close to the gap to cause an interaction between the first and the second magnetic fields, thereby adjusting deposition distribution of the particles in the deposition surface.

With such a vacuum film forming apparatus, the deposition distribution of particles that are deposited on a deposition surface of works can be deliberately varied by an interaction of the magnetic fields so as to cancel the non-uniformity in the deposition of the particles in the deposition surface of the works, which is caused by defects in fitting the works.

The vacuum film forming apparatus may be configured such that the first and second hollow frame members respectively have first and second targets used for sputtering and are made of different compositions, and that an alloy film is deposited on the deposition surface by particles ejected from the first and second targets by sputtering due to the first and second magnetic fields.

The vacuum film forming apparatus may be configured to further comprise a first cylindrical plate disposed between the first hollow frame member and the first magnetic field forming device, and a second cylindrical plate disposed between the second hollow frame member and the second magnetic field forming device, and to use the first plate and the second plate as an anode and a cathode alternately.

The foregoing and other objects, features, and advantages of the present invention will become more readily apparent from the following detailed description of preferred embodiments of the invention, with reference to the accompanying drawings.

### ADVANTAGES OF THE INVENTION

The present invention makes available a vacuum film forming apparatus that is intended to use a portion of a cylindrical member (more precisely, a substantially cylindrical member made of a plurality of curved members each curved in a sector shape) as a sputtering target and moreover to have an additional function of plasma polymerization using the cylindrical member.

The present invention also makes available a vacuum film forming apparatus that can appropriately cope with the non-uniformity in the target erosion originating from the magnetic field conditions at the axial ends of a target that curves widthwise and extends axially, when forming the magnetic field along the width of the curved surface of the target.

The present invention also makes available a vacuum film forming apparatus that adjusts deposition distribution of particles deposited on a substrate by an interaction of magnetic fields generated by magnetic field forming devices that are provided in a pair of hollow frame members disposed adjacent to each other.

### BRIEF DESCRIPTION OF THE DRAWINGS

FIG. 1 is a cross-sectional view of a vacuum film forming apparatus according to one embodiment of the invention, illustrating a cross section of a cylindrical hollow frame member disposed inside a vacuum chamber.

FIG. 2 is a cross-sectional view of the vacuum film forming apparatus according to the embodiment, illustrating a cross-sectional view along the axial direction of its hollow frame member.

FIG. 3 is a plan view illustrating the arrangement relationship between a hollow frame member and an earth shield plate viewed along the center axis of the hollow frame member.

FIG. 4(a) is a plan view (viewed along the axis of the target) illustrating the arrangement of magnets disposed on a back surface of the target, FIG. 4(b) is a view schematically illustrating the shape of an erosion formed on a target surface, which originates from the magnetic fields of the magnets, shown together with an opening in the earth shield plate, and FIG. 4(c) is a view schematically illustrating the positional relationship between the earth shield plate and the target in a cross section taken along line C-C in FIG. 4(b).

### DESCRIPTION OF THE REFERENCE NUMERALS

10 interior space
10a upper interior space
10b lower interior space
11 container
12 bottom lid
13 vacuum chamber
14 gap
15 first hollow frame member
16 second hollow frame member
17 opening
17a end surface of the opening
18 earth shield plate
19 servomotor
20 timing belt
21 first pulley
22 second pulley,
23 works
23a deposition surface
24 insulator
25 O-ring
26 gas introduction port
27 gas exhaust port
28 MF power supply
29 fastening device
30 backing plate
31 first curved member (sputtering target)
32 second curved member (metal plate for plasma polymerization)
33 magnetic field forming device
34 magnet
34a first rod-shaped magnet
34b second rod-shaped magnet
34c third rod-shaped magnet
34d first sector-shaped magnet
34e second sector-shaped magnet
35 yoke portion
36, 37 magnetic field
40 bracket
41 pipe
43 cooling water
44, 47 through hole
46 flat plate bearing metal
46a flange portion of the flat plate bearing metal
48 flange
48 flange portion of the flange
49 rotation sealing portion
50 water passage area
51 cooling water port
60 erosion
60a major axis erosion
60b minor axis erosion

### BEST MODE FOR CARRYING OUT THE INVENTION

Hereinbelow, preferred embodiments of the present invention are described with reference to the drawings.

Hereinbelow, with reference to the drawings, embodiments of the present invention are described.

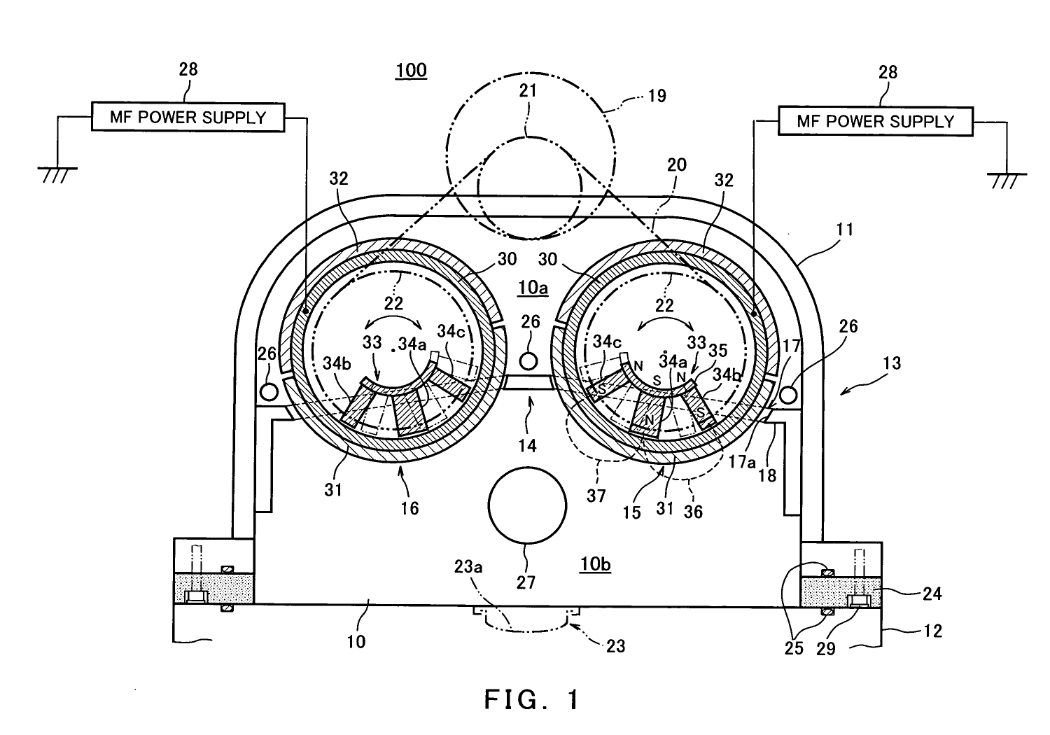

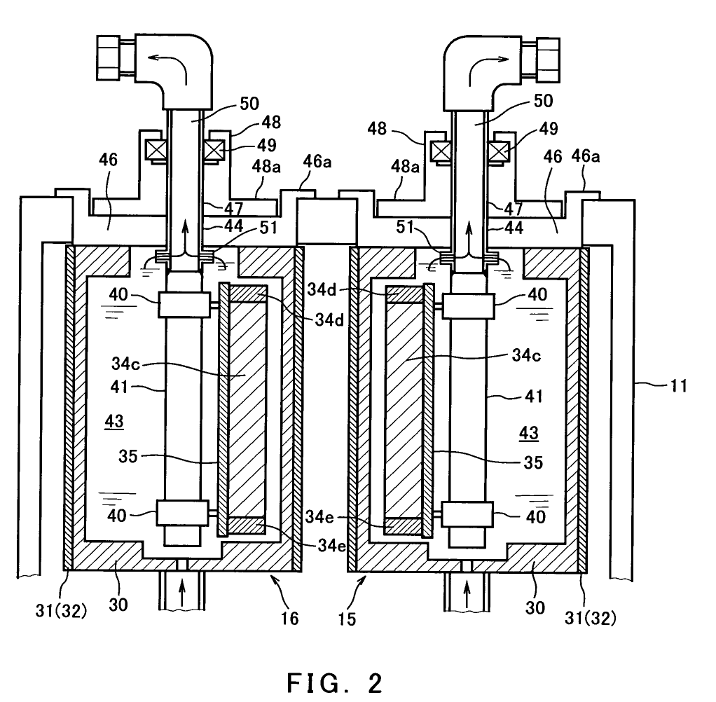

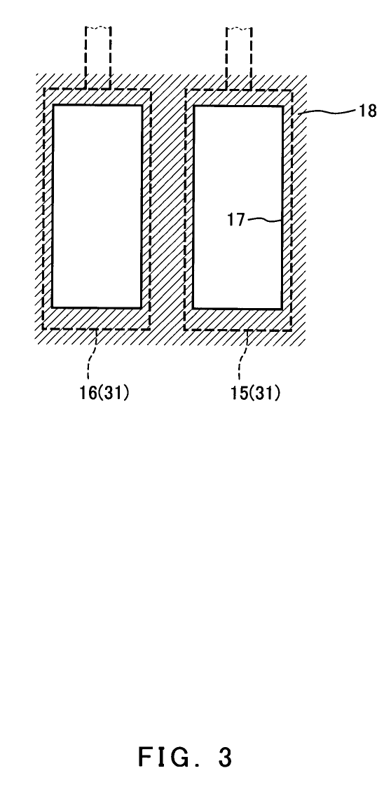

FIGS. 1 and 2 are cross-sectional views of a vacuum film forming apparatus according to the present embodiment. More specifically, FIG. 1 is a cross-sectional view illustrating, in cross section, cylindrical hollow frame members disposed inside the vacuum chamber, and FIG. 2 is a cross-sectional view taken along the axes of the hollow frame members. FIG. 3 is a plan view illustrating the positional relationship between the hollow frame members and an earth shield plate, viewed along the center axes of the hollow frame members.

The vacuum film forming apparatus 100 primarily comprises a vacuum chamber 13, a pair of first and second hollow cylindrical frame members 15 and 16, an electrically conductive earth shield plate 18 (shield plate), a servomotor 19, a timing belt 20, a first pulley 21, a pair of second pulleys 22, and a pair of driving devices (not shown). The vacuum chamber 13 comprises an electrically conductive container 11 and a bottom lid 12 that permits an interior space 10 thereof for keeping a predetermined gas atmosphere to reduce the pressure. The pair of first and second hollow cylindrical frame members 15 and 16 are arranged inside the interior space 10 so as to be lined up and spaced apart at a gap 14. The electrically conductive earth shield plate 18 (shield plate) has an opening 17 facing toward the central axis portions the of the first and second hollow frame members 15 and 16. The servomotor 19 is for generating a driving force for rotating the first and second hollow frame members 15 and 16. The timing belt 20 is for transferring the driving force of the servomotor 19 to the first and second hollow frame members 15 and 16. The first pulley 21 is coupled to the shaft of the servomotor 19, and the timing belt 20 is looped over the first pulley 21. The second pulleys 22 are coupled to the first and second hollow frame members 15 and 16, respectively, and the timing belt 20 is looped over the second pulleys 22. The driving devices are for rotating magnetic field forming devices 33 (described later), which are provided respectively in the first and second hollow frame members 15 and 16, circumferentially along the inner circumferential surfaces of the first and second hollow frame members 15 and 16, independently from the rotation of the first and second hollow frame members 15 and 16.

It should be noted that FIG. 1 illustrates an example in which both the first and second hollow frame members 15 and 16 are rotated in the same direction (both are rotated clockwise or anticlockwise) by the timing belt 20, but this is for illustrative purposes only. It is also possible to employ the configuration in which the two hollow frame members are rotated in different directions from each other; for example, the first hollow frame member 15 may be rotated clockwise while the second hollow frame member 16 may be rotated anticlockwise.

When the first and second hollow frame members 15 and 16 can be rotated, it is made possible to maximize the life span of the sputtering target by controlling the sputtering so that the sputtering, as will be discussed in detail later, can uniformly scrape away the curved surface of the sputtering target.

Also here, works 23 formed by molding plastic with a metal mold is disposed on the bottom lid 12 such that a deposition surface 23a thereof is exposed to the interior space 10, and a deposition film made by sputter particles and a plasma polymerization reaction is formed on the deposition surface 23a of the works 23.

The container 11 is disposed on the bottom lid 12 with an annular insulator 24 interposed therebetween, and the bottom lid 12, the insulator 24, and the container 11 are connected to one another by fastening device 29, such as bolts, with the interior space 10 being hermetically closed by O-rings 25.

The electrically conductive earth shield plate 18, which divides the interior space 10 surrounded by the container 11 and the bottom lid 12 vertically into two spaces, an upper interior space 10a and a lower interior space 10b, is provided for the purpose of preventing abnormal electric discharge.

More specifically, as will be appreciated from FIGS. 1 and 3, the earth shield plate 18 is disposed in the following manner. A curved surface of a curved member 31, which is electrically conductive and is made by bending a flat plate into a sector shape (the same applied to a second curved member 32; described later), opposes an end surface 17a of the opening 17, which faces toward the central portion of the curved surface of the first curved member 31, and protrudes from the opening 17 toward the lower interior space 10b through the opening 17. The opening 17, which has a width narrower than the width of the first curved member 31, is brought close to the curved surface of the first curved member 31.

The earth shield plate 18 is connected to the container 11 (the vacuum chamber 13) in a grounded state, and is disposed in such a manner that the opening 17 of the earth shield plate 18 is brought sufficiently close to the surface of the first curved member 31 while it is kept insulated from the first curved member 31.

In this way, even if a high electric power is applied to the first curved member 31, no electric discharge occurs between the earth shield plate 18 and the first curved member 31. Consequently, the plasma generated by gas ionization due to electric discharge disappears at the end surface 17a (the perimeter of the opening 14) of the opening 17 in the earth shield plate 18, preventing abnormal electric discharge in the vicinity of the earth shield plate 18 appropriately.

Accordingly, when a mid frequency power of about 10 KHz to about 350 KHz is applied to the first curved member 31 via an electrically conductive backing plate 30 (described later), electric discharge is caused between the first curved member 31 and the vacuum chamber 13. Consequently, plasma made of electrons and gas ions originating from ionization of gas (for example, Ar gas) is appropriately formed in the lower interior space 10b, and the plasma can be trapped in the lower interior space 10b by the earth shield plate 18. Thus, plasma formation can be sustained appropriately.

Moreover, the earth shield plate 18 covers the curved surface of the first curved member 31 at both longitudinal (axial) end portions, which makes it possible to appropriately cope with the non-uniformity in target erosion originating from the magnetic field conditions at the axial ends of the first curved member 31 (in the case where the first sector-shaped frame member 31 is a sputtering target), as will be discussed in detail later.

A sidewall portion of the container 11 that is within the upper interior space 10a is provided with three gas introduction ports 26, which are connected to a gas supply source (now shown), while a sidewall portion of the container 11 that is within the lower interior space 10b is provided with one gas exhaust port 27, which is connected to an evacuation apparatus (not shown). Thus, after predetermined gas is introduced toward the upper interior space 10a from the gas introduction ports 26, the gas passes through the gap between the end surface 17a of the opening 17 of the earth shield plate 18 and the surfaces of the first and second hollow frame members 15 and 16, flowing into the lower interior space 10b. The gas is eventually let out through the gas exhaust port 27 to outside of the container 11.

Since the gas introduction ports 26 are provided in the upper interior space 10a region, the pressure in the upper interior space 10a becomes higher than in the lower interior space 10b. Consequently, the sputter particles generated in the lower interior space 10b are hindered from entering the upper interior space 10a, and the contamination in the upper interior space 10a due to the sputter particles can be prevented appropriately.

As for the kind of gas that is introduced into the interior space 10 of the container 11, Ar gas is used when an aluminum film is to be formed by sputtering, while mixture gas comprised of Ar gas and HMDS gas is used when a SiOx film is formed by plasma polymerization. When a functional material such as TiN is to be formed by reactive sputtering, it is necessary to add nitrogen gas.

Hereinbelow, the configuration of the first and second hollow frame members 15 and 16 is described in detail with reference to FIGS. 1 and 2.

It should be noted that since the first and second hollow frame members 15 and 16 have the same configuration, only the configuration of the first hollow frame member 15 will be described herein and the description of the configuration of the second hollow frame member 16 will be omitted.

As illustrated in FIG. 1, the structure of the first hollow frame member 15 in cross section primarily comprises a cylindrical backing plate 30 made of a metal (for example, copper), the first and second curved members 31 and 32 that are curved in a sector shape and disposed on an outer circumferential surface of the backing plate 30.

Inside the backing plate 30, a magnetic field forming device 33 is disposed along the inner circumferential surface of the backing plate 30.

The backing plate 30 is, as illustrated in FIG. 1, connected to a mid frequency (MF) power supply 28 via a predetermined cable, by which mid frequency power for forming plasma is applied to the backing plate 30.

As illustrated in FIG. 2, this backing plate 30 also serves as a water reservoir member that reserves cooling water 43 for cooling the magnetic field forming device 33 and so forth. The circulation passage of the cooling water 43 will be discussed later.

Each of the first and second curved members 31 and 32 has a curved surface that curves widthwise and extends axially, with the curved surface having a substantially uniform curvature with respect to the axis. The configuration of the first and second curved members 31 and 32 combined forms a substantially cylindrical frame member that covers almost all the outer circumferential surface of the backing plate 30. Each of the first and second curved members 31 and 32 has such an outer shape that a cylinder is axially divided approximately in half. The shape of the curved members is not limited to this shape, and it may be such a shape that a cylindrical shape is divided into quarters.

The first curved member 31 may be a target used for a sputtering apparatus. For example, when aluminum is to be sputtered, the first curved member 31 is an aluminum target.

On the other hand, a region of the substantially cylindrical frame member other than the curved member that serves as the sputtering target can be used for plasma polymerization, so the second curved member 32 may be a stainless metal plate or a ceramic plate that is used for plasma polymerization deposition but is not easily sputtered.

In order that a magnetic field (leakage magnetic flux) can be reliably formed over the outer circumferential surfaces of the first and second curved members 31 and 32, the magnetic field forming device 33 comprises a plurality of magnets 34, and a sector-shaped yoke portion 35 with which one side face of each of the magnets 34 is in intimate contact so that the magnets 34 can be held, and that is curved to be concentric with the backing plate 30 and approximately parallel to the inner circumferential surface of the substantially cylindrical frame member.

As with the first hollow frame member 15 (the first curved member 31), the magnetic field forming device 33 is also configured to be rotatable circumferentially along the inner circumferential surface of the first hollow frame member 15 (more precisely, the inner circumferential surface of the backing plate 30) by an appropriate driving device (not shown), independently from the rotation of the first hollow frame member 15 (the first curved member 31), for the purpose of maximizing the life span of the target by controlling the sputtering so as to scrape away the curved surface of the sputtering target uniformly.

However, the range of rotation of the magnetic field forming device 33 is restricted within the plasma formation region in the lower interior space 10b, and as indicated by the solid lines and the fine dot-dashed lines in FIG. 1, the magnetic field forming device 33 is configured to swing along the inner circumferential surface of the backing plate 30 within a region corresponding to the portion of the first curved member 31 that protrudes from the opening 17 of the earth shield plate 18.

As will be appreciated from FIGS. 1, 2, and 4(a), the magnets 34 that constitute the magnetic field forming device 33 more specifically comprises a first rod-shaped magnet 34a, a second rod-shaped magnet 34b, a third rod-shaped magnet 34c, a first sector-shaped magnet 34d, and a second sector-shaped magnet 34e. The first rod-shaped magnet 34a is fitted to the center of the yoke portion 35 such that it extends parallel to the axis of the backing plate 30 with its south pole facing approximately at the circumferentially center of the sector-shaped yoke portion 35 and its north pole facing the backing plate 30. The second rod-shaped magnet 34b is fitted to one circumferential end of the yoke portion 35 such that it extends parallel to the axis of the backing plate 30 with its north pole facing one circumferential end of the yoke portion 35 and its south pole facing the backing plate 30. The third rod-shaped magnet 34c is fitted to the other circumferential end of the yoke portion 35 such that it extends parallel to the axis of the backing plate 30 with its north pole facing at the other circumferential end of the yoke portion 35 and its south pole facing at the backing plate 30. The first sector-shaped magnet 34d curves and extends such that the first, second, and third rod-shaped magnets 34a, 34b, and 34c are connected to one another at their one axial ends to form a magnetic circuit, and the first sector-shaped magnet 34d is fitted to the one ends. The second sector-shaped magnet 34e curves and extends such that the first, second, and third rod-shaped magnets 34a, 34b, and 34c are connected to one another at their other axial ends to form a magnetic circuit, and the second sector-shaped magnet 34e is fitted to the other ends.

Thus, as indicated by a dashed line in FIG. 1, by the north pole of the first rod-shaped magnet 34a and the south pole of the second rod-shaped magnet 34b, a magnetic field 36 is formed over the curved surface of the first curved member 31 along the width of the curved surface (the magnetic field 36 formed in the vicinity of the outer circumferential surface of the first hollow frame member 15 and along the circumference thereof). Likewise, as indicated by a dashed line in FIG. 1, by the north pole of the first rod-shaped magnet 34a and the south pole of the third rod-shaped magnet 34c, a magnetic field 37 is formed over the curved surface of the first curved member 31 along the width of the curved surface (the magnetic field 37 formed in the vicinity of the outer circumferential surface of the first hollow frame member 15 and along the circumference thereof).

As illustrated in FIG. 2, the structure along the axis of the first hollow frame member 15 includes an annular flat plate bearing metal 46, a cylindrical flange 48, an annular rotation sealing portion 49, and an annular second pulley 22 (see FIG. 1). The flat plate bearing metal 46 has a flange portion 46a that can be positioned while it is being in intimate contact with, and being fitted into, an opening formed in a sidewall of the container 11, and it comes into contact with an axial end portion of the backing plate 30 in the state in which a pipe 41 is pierced through a through hole 44. The flange 48 has a flange portion 48a that is in intimate contact with the flat plate bearing metal 46 in the state in which the pipe 41 is pierced through the through hole 47, as with the flat plate bearing metal 46. The rotation sealing portion 49, disposed in the through hole 47 of the flange 48, allows the pipe 41 and the magnetic field forming device 33 to be rotatable with an appropriate driving device. The second pulley 22 (see FIG. 1), fastened to an outer circumferential surface of the flange 48, rotates the backing plate 30, the first and second curved members 31 and 32, the flat plate bearing metal 46, and the flange 48 by being wrapped around by the timing belt 20 (see FIG. 1) to which the driving force from the servomotor 19 (see FIG. 1) is transferred.

As will be appreciated from FIG. 2, since the magnetic forming device 33 and the pipe 41 are fastened to the flange 48 via the rotation sealing portion 49, the magnetic field forming device 33 and the pipe 41 can rotate (swing) independently from the rotation of the first hollow frame member 15.

The pipe 41 is configured to hold the magnetic field forming device 33 by a pair of brackets 40 and extend from the interior of the backing plate 30 through a through hole 44 and a through hole 47 to outside. The pipe 41 is also configured to have a water passage area 50 for passing the cooling water 43 inside its axially upper portion. Specifically, the cooling water 43 that has filled almost the entire region of the backing plate 30 and cooled the magnetic field forming device 33 flows through a cooling water port 51 of the pipe 41 into the water passage area 50 inside the pipe 41, whereby the cooling water 43 is circulated as indicated by the arrows in FIG. 2 while it is being adjusted to be at an appropriate temperature.

It should be noted that although various fixed contact surfaces and sliding contact surfaces of the components shown in FIG. 2 are provided with vacuum sealing such as O-rings as needed, detailed illustrations and explanations thereof are omitted herein.

Hereinbelow, the advantageous effects exhibited by the vacuum film forming apparatus 100 and the operations (reasons) that produce such effects will be discussed.

Firstly, in the vacuum film forming apparatus 100 according to the present embodiment, the curved surface is covered at both axial end portions of the first curved member 31 (the same applies to the second curved member 32) by the earth shield plate 18, and therefore, when using the first curved member 31 as a sputtering target (hereinafter, the first curved member 31 is referred to as a “target 31”), the vacuum film forming apparatus 100 makes it possible to appropriately cope with the non-uniformity in target erosion originating from the magnetic field conditions at the axial ends of the target 31.

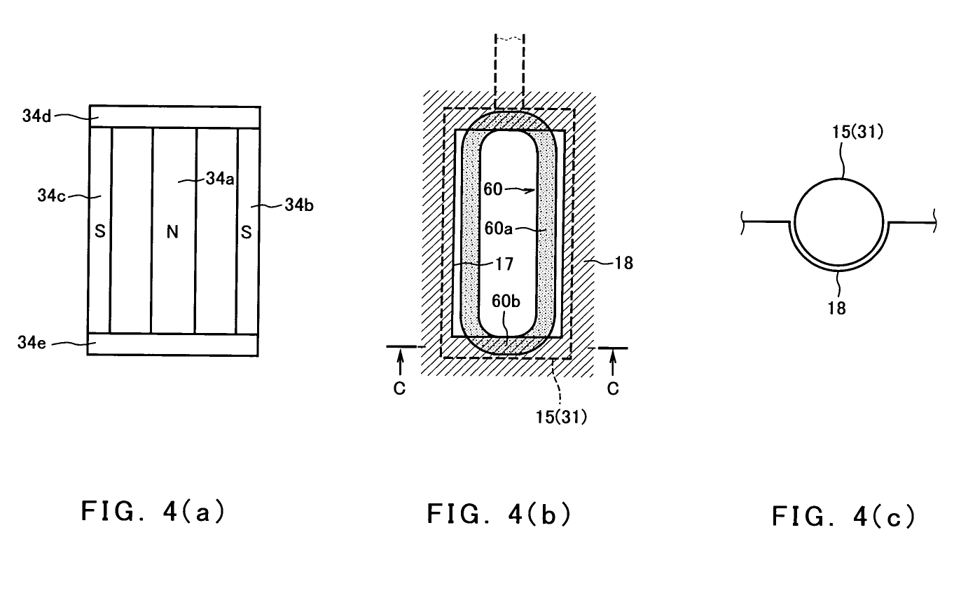

The reason why such an effect is exhibited will be discussed in detail with reference to FIG. 4. Herein, an example of sputtering for the target 31 with Ar gas is described in which Ar gas is introduced through the gas introduction ports 26 into the lower interior space 10b.

FIG. 4(a) is a plan view (viewed along the axis of the target) illustrating the arrangement of the magnets disposed on a back surface of the target, FIG. 4(b) is a view schematically illustrating the shape of an erosion formed on the target surface, which originates from the magnetic fields of the magnets, shown together with the opening in the earth shield plate, and FIG. 4(c) is a view schematically illustrating the positional relationship between the earth shield plate and the target in a cross section taken along line C-C in FIG. 4(b).

The first to third rod-shaped magnets 34a, 34b, 34c are, as have already been mentioned, the magnets for forming the magnetic fields 36 and 37 (see FIG. 1) substantially parallel to the curved surface of the target 31 in the vicinity of the outside of the curved surface and along the width of the curved surface.

By the electrons trapped by the magnetic fields 36 and 37, Ar gas (Ar atoms) undergoes ionization along the magnetic fields 36 and 37, generating high density plasma comprised of Ar ions (Ar⁺) and electrons. When a negative voltage is applied to the backing plate 30, positively ionized (or excited) Ar ions in a plasma state accelerate toward the backing plate 30 and collide with the curved surface of the target 31. Consequently, target atoms (for example, aluminum atoms) that are present in the curved surface are ejected therefrom because of the collision energy. In this way, because of the ejection of the target atoms that have been present the surface of the target 31, the curved surface of the target 31 is gradually scraped away and is made thin thicknesswise.

The portion in which the thickness of the target 31 has become thin corresponds to an erosion 60. More specifically, in the horseshoe-shaped (elliptic) erosion 60 shown in FIG. 4(b), the erosion 60a along the major axis is formed by the magnetic fields 36 and 37.

Here, when the major axis erosion 60a reaches the backing plate 30 that is below the target 31 as the depth of the major axis erosion 60a increases and the target 31 is completely scraped away thicknesswise of the target 31, the target 31 is no longer usable and the target 31 needs to be replaced. For this reason, for the purpose of maximizing the life span of the target 31, the first to third rod-shaped magnets 34a, 34b, 34c are swung circumferentially or the target 31 itself is rotated in a circumferential direction, to control the sputtering so that the curved surface of the target 31 is scraped away uniformly by sputtering.

On the other hand, the first and second sector-shaped magnets 34d and 34e are for stabilizing the magnetic circuits between the first to third rod-shaped magnets 34a, 34b, 34c and thereby improving the balance of the magnetic fields generated at both axial ends of the first to third rod-shaped magnets 34a, 34b, 34c, and therefore they are not necessarily indispensable magnets. Rather, it is desirable that the sector-shaped magnets 34d and 34e be eliminated if the defects originating from instability in the magnetic circuits can be resolved by a technique that will be explained hereinbelow, since fabrication of such sector-shaped magnets is troublesome.

In view of the circumstances described above, the influence of the first and second sector-shaped magnets 34d and 34e on the erosion formation in the target 31 will be discussed in two different cases: in one case the first and second sector-shaped magnets 34d and 34e are disposed on the respective axial ends of the first to third rod-shaped magnets 34a, 34b, 34c, while in the other case no sector-shaped magnet is provided on the axial ends.

First, the case in which the first and second sector-shaped magnets 34d and 34e are provided will be discussed.

When the first and second sector-shaped magnets 34d and 34e are disposed on the respective axial ends of the first to third rod-shaped magnets 34a, 34b, 34c, erosions 60b along the minor axis in the horseshoe-shaped (elliptic) erosion 60 shown in FIG. 4(b) is formed due to the influence from the magnetic fields formed by the first and second sector-shaped magnets 34d and 34e.

The regions of these minor axis erosions 60b become wider in a circumferential direction than the region of the major axis erosion 60a, and consequently, even if the first and second sector-shaped magnets 34d and 34e are swung circumferentially or the target 31 is rotated circumferentially, the degree of depthwise progress of the minor axis erosions 60b becomes quicker than the degree of depthwise progress of the major axis erosion 60a. Thus, the life span of the target 31 is dominated by the degree of depthwise progress of the minor axis erosions 60b. As a result, the target 31 cannot be used uniformly over the entire region of its curved surface, and some of the material of the target 31 is wasted.

In view of this, as will be appreciated from FIGS. 4(b) and 4(c), the axial length of the opening 17 of the earth shield plate 18 is adjusted such that both axial end portions of the target 31 corresponding to the region in which the minor axis erosions 60b are formed can be covered, and the earth shield plate 18 is bent in a headband-like shape along the curve of the curved surface located at both axial end portions of the target 31. By doing so, the curved surface is covered appropriately at both axial end portions of the target 31 by the earth shield plate 18, and the formation of the minor axis erosions 60b is suppressed.

Accordingly, the earth shield plate 18 serves to improve the non-uniformity in target erosion (rapid progress of erosion) originating from the magnetic field conditions at the axial ends of the target 31.

Next, the case in which no first and second sector-shaped magnets 34d or 34e is provided will be discussed.

When the first and second sector-shaped magnets 34d and 34e are provided at neither axial end of the first to third rod-shaped magnets 34a, 34b, 34c, the magnetic circuits at both the axial ends of the first to third rod-shaped magnets 34a, 34b, 34c become unstable. Therefore, formation of the major axis erosion 60a is disordered because of an imbalance of the magnetic fields at both axial ends of the first to third rod-shaped magnets 34a, 34b, 34c.

In view of this, as will be appreciated from FIGS. 4(b) and 4(c), the axial length of the opening 17 of the earth shield plate 18 is adjusted such that the earth shield plate 18 can cover the regions at both axial end portions of the target 31 corresponding to the regions in which the major axis erosion 60a is disordered, and the earth shield plate 18 is bent in a headband-like shape so as to conform to the curve shapes of the curved surface located at both axial end portions of the target 31, in a similar manner to the above.

Accordingly, under this condition, the earth shield plate 18 serves to improve the non-uniformity in target erosion (disorder in the shape of erosion) originating from the magnetic field conditions in the axial ends of the target 31.

In this way, an increased efficiency (longer lifespan of the target) in the film formation process can be achieved with the vacuum film forming apparatus 100.

Secondly, the vacuum film forming apparatus 100 according to the present embodiment makes it possible to perform sputter deposition using, as a sputtering target, the first curved member 31 of the substantially cylindrical member that comprises the first and second curved members 31 and 32, and also to perform plasma polymerization deposition using a material that is not easily sputtered, such as a metal or ceramic material, for the second curved member 32.

Hereinbelow, an operation of the vacuum film forming apparatus 100 will be described taking a plasma reaction at the surface of the first hollow frame member 15 shown in FIG. 1 as an example. It should be noted that the plasma reaction in the second hollow frame member 16 is also the same as the reaction that will be described hereinbelow, so the detailed description thereof will be omitted.

Herein, an example is described in which an aluminum film is formed on the deposition surface 23a of the works 23 by sputtering with Ar gas introduced into the lower interior space 10b of the vacuum chamber 13 and thereafter a SiOx film is stacked over the aluminum film by plasma polymerization with HMDS gas introduced into the lower interior space 10b of the vacuum chamber 13. Accordingly, an aluminum target is used as the first curved member 31, and a stainless metal plate or a ceramic plate is used as the second curved member 32.

First, a rotation position of the first hollow frame member 15 is determined by the servomotor 19 in order that the first curved member (aluminum target) will be exposed to the lower interior space 10b of the vacuum chamber 13. In this state, the evacuation apparatus is operated to evacuate the interior space 10 of the vacuum chamber 13 through the gas exhaust port 27, so that the pressure of the interior space 10 of the vacuum chamber 13 is reduced to a predetermined vacuum condition.

Then, Ar gas as atmosphere gas for plasma formation is introduced from the gas supply source through the gas introduction ports 26 into the lower interior space 10b of the vacuum chamber 13. At the same time, the MF power supply 28 is operated so that a MF power 28 of about 10 KHz to about 350 KHz is applied to the backing plate 30. Thus, as has already been discussed, aluminum atoms in the surface of the first curved member 31 (aluminum target) are ejected therefrom as particles that are to be deposited on the deposition surface 23a of the works 23 by a sputtering action, and thereby, an aluminum film is formed on the deposition surface 23a of the works 23.

Subsequently, the first hollow frame member 13 is rotated about 180° by the servomotor 19, whereby the second curved member 32 (for example, a stainless metal plate) is exposed to the lower interior space 10b of the vacuum chamber 13. Then, while the above-described plasma condition is being sustained, HMDS gas as source gas for plasma polymerization is introduced from the gas supply source through the gas introduction ports 26 into the lower interior space 10b of the vacuum chamber 13. Consequently, HMDS monomer particles are activated through excitation by the plasma, and thereafter, the activated monomer particles of HMDS are turned into a HMDS polymer through a radical polymerization reaction. The HMDS that has become a polymer through the radical polymerization is deposited on the aluminum film of the works 23, and thus, a SiOx film is formed on top of the deposition surface 23a. At this time, the X value in SiOx can be varied from SiO to SiO₂ by introducing gas such as O₂, O₃, and N₂O in the radical polymerization reaction.

It should be noted that dual magnetron driving is performed here in which the backing plate 30 that is disposed between the first hollow frame member 15 and the magnetic field forming device 33 in the first hollow frame member 15 and the backing plate 30 that is disposed between the second hollow frame member 16 and the magnetic field forming device 33 in the second hollow frame member 16 are used in pair as an anode and cathode alternately.

In this way, the vacuum film forming apparatus 100 makes it possible to form an aluminum film formed by sputtering and a SiOx film formed by plasma polymerization continuously over the deposition surface 23a of the works 23.

Thereby, the formation of an aluminum film and the formation of an SiOx film can be switched from one to the other quickly, and an increased efficiency in the film formation process (shortening of cycle time) can be achieved with the vacuum film forming apparatus 100.

Thirdly, the vacuum film forming apparatus 100 according to the present embodiment makes it possible to adjust the deposition distribution of the particles deposited on the deposition surface 23a of the works 23 by the interaction between the magnetic fields formed by the magnetic field forming devices 33 existing in the pair of the first and second hollow frame members 15 and 16, which are disposed adjacent to each other.

One example of the magnetic field interaction between the magnetic field forming devices 33 is as follows. When the respective magnetic field forming devices 33 provided in the first and second hollow frame members 15 and 16 are rotated in such a manner that they will both come closer to the gap 14 as indicated by the fine dot-dashed lines in FIG. 1, the magnetic flux distributions in the magnetic fields 37 are affected each other because the third rod-shaped magnets 34c of the two magnetic field forming devices 33 come close to each other. This makes it possible to deliberately vary the deposition distribution of the particles deposited on the deposition surface 23a of the works 23 by the interaction between the magnetic fields 37 so that, for example, the non-uniformity in deposition of particles on the deposition surface 23a of the works 23 that is caused by defects in fitting of the works 23 can be cancelled.

### MODIFIED EXAMPLE 1

One example of the works 23 is a substrate formed by metal-molding a plastic. In the case of forming a predetermined film on a plastic substrate made by metal-molding with the vacuum film forming apparatus 100, it is possible to use a metal mold to which the plastic substrate is attached as the bottom lid 12 shown in FIG. 1.

Nevertheless, each time a film is formed on the plastic substrate, the interior space 10 of the vacuum film forming apparatus 100 is inevitably released to the atmosphere in synchronization with the mold cycle time of the plastic substrate. For this reason, it is important to reduce the pressure in the interior space 10 of the vacuum film forming apparatus 100 quickly to the level that can be matched with the molding cycle time. For example, when the interior space 10 of the vacuum film forming apparatus 100 is roughly evacuated with a roughing vacuum pump, it is desirable that the moisture contained in the interior space 10 be removed quickly by introducing Ar gas into the interior space 10. It is also effective to use an ultra low temperature cooling apparatus provided for the exhaust system to cause it to adsorb the moisture.

### MODIFIED EXAMPLE 2

The description has discussed so far examples in which the first curved member 31 and the second curved member 32 are formed in a sector shape (more precisely, in a semi-circular sector shape), and the first curved member 31 is used as a sputtering target while the second curved member is used as a metal plate for plasma polymerization. However, the configurations of the members 31 and 32 are not limited thereto. For example, the first curved member 31 may be used as a cylindrical sputter target. This enables the life span of the sputtering target to be prolonged to the maximum.

Moreover, both the first curved member 31 and the second curved member 32 may be sector-shaped sputtering targets, and the first curved member 31 and the second curved member 32 may have different compositions of the materials. For example, when the material for the first curved member 31 is aluminum, the material for the second curved member 32 may be different from the sputter target material used as the first curved member 31; for example, it may be a sputter target made of a material such as titanium, chromium, copper, or gold. Thus, when a joint between the first curved member 31 and the second curved member 32 enters the lower interior space 10b, both materials of the first curved member 31 and the second curved member 32 are sputtered at the same time, so an alloy film made of the two materials can be deposited on the deposition surface 23a of the works 23.

If the vacuum film forming apparatus 100 is used in such a way, a member for plasma polymerization (for example, a stainless metal plate) cannot be used as the second curved member 32, and the vacuum film forming apparatus 100 is used as an apparatus specialized in sputter deposition.

### MODIFIED EXAMPLE 3

The configuration of the second hollow frame member has not been elaborated on thus far, assuming that the configuration of the first hollow frame member 15 and the configuration of the second hollow frame member 16 are the same. However, the composition of the material for the sputtering target of the first hollow frame member 16 may be different from that of the second hollow frame member.

For example, it is possible to use aluminum as the material for the sputtering target of the first hollow frame member 15 and a metal other than aluminum, such as titanium, chromium, copper, or gold, as the material for the sputtering target of the second hollow frame member 16. By doing so, an alloy film is deposited on the deposition surface 23a of the works 23 by the particles ejected from the sputtering targets of the first hollow frame member 15 and the second hollow frame member 16.

### MODIFIED EXAMPLE 4

Although the description has discussed thus far examples in which the range of rotation of the magnetic field forming devices 33 is restricted within the plasma formation region in the lower interior space 10b, the vacuum film forming apparatus may be configured so that the magnetic field forming devices 33 can enter the upper interior space 10a region.

Even when the curved member (for plasma polymerization) is contaminated by being exposed to plasma in plasma polymerization deposition (when a polymerized film is deposited), it is possible to transferring the contaminated portion to the upper interior space 10a by rotating it so that the contaminated portion can be cleaned. Specifically, the contaminated portion of the curved member is rotation-transferred to the upper interior space 10a, and the magnetic field forming device 33 is likewise rotation-transferred to the upper interior space 10a so as to correspond to the contaminated portion. When a sputtering operation is performed in this condition, the contaminant adhered to the curved member can be scraped away by the sputtering operation.

In this case, it is desirable that a baffle plate be provided at an appropriate location of the upper interior space 10a, in order to prevent the peeled material from adhering a wall surface of the upper interior space 10a again.

In addition, the above-described apparatus that is capable of executing a cleaning operation makes it possible to clean the target as needed even when the entire curved member is configured to be a cylindrical target, and consequently, it becomes possible to use the cylindrical target as an electrode in the plasma polymerization deposition.

From the foregoing description, numerous improvements and other embodiments of the present invention will be readily apparent to those skilled in the art. Accordingly, the foregoing description is to be construed only as illustrative examples and as being presented for the purpose of suggesting the best mode for carrying out the invention to those skilled in the art. Various changes and modifications can be made in specific structures and/or functions substantially without departing from the scope and spirit of the invention.

### INDUSTRIAL APPLICABILITY

The vacuum film forming apparatus according to the present invention is useful as an apparatus for forming a multilayer film in a reflector for vehicle headlights or taillights.

1. A vacuum film forming apparatus comprising:
an electrically conductive vacuum chamber having an interior space;
a target disposed in the interior space, the target having a curved surface curving widthwise and extending axially;
a magnetic field forming device configured to form a magnetic field along the width of the curved surface of the target; and
an electrically conductive shield plate having an opening that faces an axially central portion of the curved surface, the electrically conductive shield plate being disposed such that the curved surface is opposed to an end surface of the opening, wherein
the curved surface that is positioned at an axial end portion of the target is covered by the shield plate.

2. The vacuum film forming apparatus according to claim 1, wherein the shield plate covers the curved surface at both axial end portions of the target.

3. The vacuum film forming apparatus according to claim 1, wherein the shield plate is bent so as to conform to a curve shape of the curved surface.

4. The vacuum film forming apparatus according to claim 1, wherein the target is in a substantially cylindrical shape comprising a plurality of curved members each curved in a sector shape.

5. The vacuum film forming apparatus according to claim 1, wherein the shield plate is an earth shield plate connected to the vacuum chamber that is in a grounded state.

6. The vacuum film forming apparatus according to claim 1, further comprising a plate disposed between the target and the magnetic field forming device, and wherein a predetermined electric power is applied to the plate, to form plasma in the vicinity of the curved surface of the target that protrudes from the opening.

7. The vacuum film forming apparatus according to claim 1, wherein the target is configured to be rotatable around its axis.

8. The vacuum film forming apparatus according to claim 7, wherein the magnetic field forming device is configured to be rotatable along the width of the curved surface of the target, independently from the rotation of the target.

9. A vacuum film forming apparatus comprising
an electrically conductive vacuum chamber having an interior space;
a frame member in which a plurality of curved members each curved in a sector shape are arranged in the interior space, to form a substantially cylindrical shape; and
a magnetic field forming device that is disposed in an interior surrounded by the frame member and is configured to form a magnetic field along the circumference of the frame member, wherein
at least one of the curved members is a target used for sputtering, and a region of the frame member other than the target is used for plasma polymerization.

10. The vacuum film forming apparatus according to claim 9, wherein the frame member is configured to be rotatable around its axis.

11. The vacuum film forming apparatus according to claim 10, wherein the magnetic field forming device is configured to be rotatable along the circumference of the frame member, independently from the rotation of the frame member.

12. The vacuum film forming apparatus according to claim 9, wherein the magnetic field forming device comprises a plurality of magnets, and a sector-shaped yoke portion being configured to hold the magnets and being substantially parallel to an inner circumferential surface of the frame member.

13. The vacuum film forming apparatus according to claim 9, further comprising:
a cylindrical plate disposed between the frame member and the magnetic field forming device, and wherein
a predetermined electric power is applied to the plate to form plasma in the vicinity of an outer circumferential surface of the frame member.

14. A vacuum film forming apparatus comprising:
an electrically conductive vacuum chamber having an interior space;
first and second hollow cylindrical frame members arranged in the interior space so as to be lined up and spaced apart from each other;
first and second magnetic field forming devices disposed inside the first hollow frame member and the second hollow frame member, respectively, the first magnetic field forming device being configured to form a first magnetic field along the circumference of the first hollow frame member and the second magnetic field forming device being configured to form a second magnetic field along the circumference of the second hollow frame member; and
a substrate having a deposition surface on which particles ejected from the first and second hollow frame members due to the first and second magnetic fields are to be deposited, the substrate being disposed such that the deposition surface is exposed to the interior space, wherein
the first and the second magnetic field forming devices are brought close to the gap to cause an interaction between the first and the second magnetic fields, thereby adjusting deposition distribution of the particles in the deposition surface.

15. The vacuum film forming apparatus according to claim 14, wherein:
the first and second hollow frame members respectively have first and second targets that are used for sputtering and are made of different compositions; and
an alloy film is deposited on the deposition surface by particles ejected from the first and second targets by sputtering due to the first and second magnetic fields.

16. The vacuum film forming apparatus according to claim 14, further comprising:
a first cylindrical plate disposed between the first hollow frame member and the first magnetic field forming device; and
a second cylindrical plate disposed between the second hollow frame member and the second magnetic field forming device, and wherein
the first plate and the second plate are used alternately as an anode and a cathode.
